(19) United States
(12) Patent Application Publication
(10) Pub. No.: US 2011/0304440 A1
(43) Pub. Date: Dec. 15, 2011

(54) RFID DEVICES USING A COMMON MASTER CLOCK AND METHODS THEREOF

(76) Inventor: Prasad Panchalan, San Jose, CA (US)

(21) Appl. No.: 12/814,108

(22) Filed: Jun. 11, 2010

(51) Int. Cl. H04Q 5/22; H03D 1/04

(52) U.S. Cl. 340/10.3; 375/346

(57) ABSTRACT

In one embodiment, a RFID reader circuit includes a master clock for providing a timing signal on a timing signal output thereof, a switching regulator synchronized with the timing signal for providing power to the RFID reader circuit, a Radio Frequency (RF) source in a transmitting path, the RF source being coupled to the timing signal output, and an analog-to-digital converter (ADC) in a receiving path, the ADC being coupled to the timing signal output. This circuit may also be included in an RFID system having a reader and a plurality of RFID tags, in one approach. According to another general embodiment, a method for mitigating noise in a RFID reader circuit includes providing a common timing signal or derivatives thereof from a master clock to each component in a RFID reader circuit and to a power supply. Other systems and methods are also shown, according to various embodiments.

### FIELD OF THE INVENTION

The present invention relates to Radio Frequency (RF) devices and methods, and more particularly, this invention relates to Radio Frequency Identification (RFID) devices using a common master clock to mitigate noise.

### BACKGROUND OF THE INVENTION

The use of Radio Frequency Identification (RFID) tags are quickly gaining popularity for use in the monitoring and tracking of items. RFID technology allows a user to remotely store and retrieve data in connection with an item utilizing a small, unobtrusive tag. As an RFID tag operates in the radio frequency (RF) portion of the electromagnetic spectrum, an electromagnetic or electrostatic coupling can occur between an RFID tag affixed to an item and an RFID reader, which is capable of reading the tag. This coupling is advantageous, as it precludes the need for a direct contact or line of sight connection between the tag and the reader.

In some currently used passive and semi-passive RFID tags, during the ‘read’ cycle, the reader generally transmits a continuous unmodulated carrier signal. A distant RFID tag includes a RF switch connected to the tag's antenna, which repetitively alternates its state at a rate called the ‘backscatter link frequency.’ This RF switch effectively modulates the carrier signal in the tag received from the transmitter, creating sidebands surrounding the carrier frequency, and separated from the carrier frequency by the backscatter link frequency. These sidebands are re-radiated by the tag's antenna, and are recovered by the reader. The above description is one typical way in which the tag communicates information to the reader. The tag does not create RF power, but instead modulates incoming RF power from the reader's transmitter, and in so doing, converts some of that incoming power to sideband frequencies which can be separately recovered by the reader. These backscatter sidebands only exist when (and because) the reader is transmitting.

In some readers, the antenna configuration is ‘monostatic’ which means that the sidebands created by the distant tag are recovered via the same antenna that the reader's transmitter uses to transmit the carrier signal. In a monostatic reader, a power amplifier is connected to a signal splitter, which is connected to an antenna and a low noise amplifier. In some other readers, the antenna configuration is ‘bistatic’ which means that the sidebands created by the distant tag are recovered by the reader via a separate antenna. A bistatic reader differs from a monostatic reader in that each reader has a power amplifier, low noise amplifier, and antenna, but in the bistatic reader, the power amplifier is connected directly to a transmit antenna, a separate receive antenna connects directly to the low noise amplifier, and there is may be signal splitter.

In some RFID reader configurations, interference can occur between the sending and receiving portions of the reader's antenna. This can be influenced by a number of different factors, but inevitably results in degradation of the reader's receiver sensitivity. Therefore, systems and methods which alleviate this problem would be particularly beneficial to the field of RFID readers and tags, as well as other RF systems employing backscatter communications.

### SUMMARY OF THE INVENTION

In one embodiment, a Radio Frequency Identification (RFID) reader circuit includes a master clock for providing a timing signal on a timing signal output thereof, a switching regulator synchronized with the timing signal for providing power to the RFID reader circuit, a Radio Frequency (RF) source in a transmitting path, the RF source being coupled to the timing signal output, and an analog-to-digital converter (ADC) in a receiving path, the ADC being coupled to the timing signal output.

In another embodiment, a RFID system includes a plurality of RFID tags and at least one RFID reader. The at least one RFID reader includes a RFID reader circuit, having a master clock for providing a timing signal on a timing signal output thereof, a RF source in a transmitting path, the RF source being coupled to the timing signal output, an ADC in a receiving path, the ADC being coupled to the timing signal output, and a digital signal recovery module in the receiving path, the digital signal recovery module being coupled to the timing signal output. Portions of the transmitting path are on a different circuit board than portions of the receiving path.

According to another embodiment, a method for mitigating noise in a RFID reader circuit includes providing a common timing signal or derivatives thereof from a master clock to each component in a RFID reader circuit and to a power supply.

Any of these embodiments may be implemented in an RFID system, which may include an RFID tag and/or interrogator (reader).

Other aspects, advantages and embodiments of the present invention will become apparent from the following detailed description, which, when taken in conjunction with the drawings, illustrate by way of example the principles of the invention.

### BRIEF DESCRIPTION OF THE DRAWINGS

For a fuller understanding of the nature and advantages of the present invention, as well as the preferred mode of use, reference should be made to the following detailed description read in conjunction with the accompanying drawings.

FIG. 1 is a system diagram of an RFID system, according to one embodiment.

FIG. 2 is a system diagram for an integrated circuit (IC) chip for implementation in an RFID tag, in one embodiment.

FIG. 3 is a partial block diagram of a RFID reader circuit according to one embodiment.

FIG. 4A is a partial block diagram of a RFID reader circuit having a common master clock, according to one embodiment.

FIG. 4B is a partial block diagram of a RFID reader circuit having a common master clock, according to another embodiment.

### DETAILED DESCRIPTION

The following description is made for the purpose of illustrating the general principles of the present invention and is not meant to limit the inventive concepts claimed herein. Further, particular features described herein can be used in combination with other described features in each of the various possible combinations and permutations.

Unless otherwise specifically defined herein, all terms are to be given their broadest possible interpretation including meanings implied from the specification as well as meanings understood by those skilled in the art and/or as defined in dictionaries, treatises, etc.

It must also be noted that, as used in the specification and the appended claims, the singular forms “a,” “an” and “the” include plural referents unless otherwise specified.

In the drawings, like and equivalent elements are numbered the same throughout the various figures.

In one general embodiment, a Radio Frequency Identification (RFID) reader circuit includes a master clock for providing a timing signal on a timing signal output thereof, a switching regulator synchronized with the timing signal for providing power to the RFID reader circuit, a Radio Frequency (RF) source in a transmitting path, the RF source being coupled to the timing signal output, and an analog-to-digital converter (ADC) in a receiving path, the ADC being coupled to the timing signal output.

In another general embodiment, a RFID system includes a plurality of RFID tags and at least one RFID reader. The at least one RFID reader includes a RFID reader circuit, having a master clock for providing a timing signal on a timing signal output thereof, a RF source in a transmitting path, the RF source being coupled to the timing signal output, an ADC in a receiving path, the ADC being coupled to the timing signal output, and a digital signal recovery module in the receiving path, the digital signal recovery module being coupled to the timing signal output. Portions of the transmitting path are on a different circuit board than portions of the receiving path.

According to another general embodiment, a method for mitigating noise in a RFID reader circuit includes providing a common timing signal or derivatives thereof from a master clock to each component in a RFID reader circuit and to a power supply.

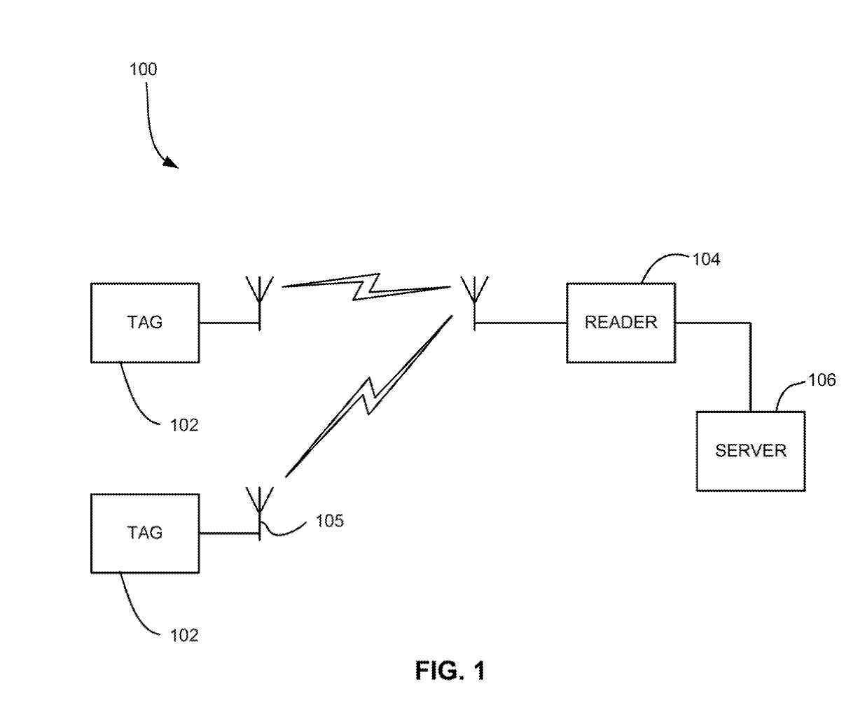

FIG. 1 depicts an RFID system 100 according to one of the various embodiments, which may include some or all of the following components and/or other components. As shown in FIG. 1, one or more RFID tags 102 are present. Each RFID tag 102 in this embodiment includes a controller and memory, which are preferably embodied on a single chip as described below, but may also or alternatively include a different type of controller, such as an application specific integrated circuit (ASIC), processor, an external memory module, etc. For purposes of the present discussion, the RFID tags 102 will be described as including a chip. Each RFID tag 102 may further include or be coupled to an antenna 105.

An illustrative chip is disclosed below, though actual implementations may vary depending on how the tag is to be used. In general terms, a preferred chip includes one or more of a power supply circuit to extract and regulate power from the RF reader signal; a detector to decode signals from the reader; a backscatter modulator to send data back to the reader; anti-collision protocol circuits; and at least enough memory to store its unique identification code, e.g., Electronic Product Code (EPC).

While RFID tags 102, according to some embodiments, are functional RFID tags, other types of RFID tags 102 include merely a controller with on-board memory, a controller and external memory, etc.

Each of the RFID tags 102 may be coupled to an object or item, such as an article of manufacture, a container, a device, a person, etc.

With continued reference to FIG. 1, a remote device 104, such as an interrogator or “reader,” communicates with the RFID tags 102 via an air interface, preferably using standard RFID protocols. An “air interface” refers to any type of wireless communications mechanism, such as the radio-frequency signal between the RFID tag and the remote device (reader). The RFID tag 102 executes the computer commands that the RFID tag 102 receives from the reader 104.

The system 100 may also include an optional backend system such as a server 106, which may include databases containing information and/or instructions relating to RFID tags and/or tagged items.

As noted above, each RFID tag 102 may be associated with a unique identifier. Such identifier is preferably an EPC code. The EPC is a simple, compact identifier that uniquely identifies objects (items, cases, pallets, locations, etc.) in the supply chain. The EPC is built around a basic hierarchical idea that can be used to express a wide variety of different, existing numbering systems, like the EAN.UCC System Keys, UID, VIN, and other numbering systems. Like many current numbering schemes used in commerce, the EPC is divided into numbers that identify the manufacturer and product type. In addition, the EPC uses an extra set of digits, a serial number, to identify unique items. A typical EPC number contains:
1. Header, which identifies the length, type, structure, version and generation of EPC;
2. Manager Number, which identifies the company or company entity;
3. Object Class, similar to a stock keeping unit or SKU; and
4. Serial Number, which is the specific instance of the Object Class being tagged.
   Additional fields may also be used as part of the EPC in order to properly encode and decode information from different numbering systems into their native (human-readable) forms.

Each RFID tag 102 may also store information about the item to which coupled, including but not limited to a name or type of item, serial number of the item, date of manufacture, place of manufacture, owner identification, origin and/or destination information, expiration date, composition, information relating to or assigned by governmental agencies and regulations, etc. Furthermore, data relating to an item can be stored in one or more databases linked to the RFID tag. These databases do not reside on the tag, but rather are linked to the tag through a unique identifier(s) or reference key(s).

RFID systems may use reflected or “backscattered” radio frequency (RF) waves to transmit information from the RFID tag 102 to the remote device 104, e.g., reader. Since passive (Class-1 and Class-2) tags get all of their power from the reader signal, the tags are only powered when in the beam of the reader 104.

The Auto ID Center EPC-Compliant tag classes are set forth below:

Class-1
Identity tags (RF user programmable, range ˜3 m)
Lowest cost

Class-2
Memory tags (20 bit address space programmable at ˜3 m range)
Security & privacy protection
Low cost

Class-3
Semi-passive tags (also called semi-active tags and battery assisted passive (BAP) tags)
Battery tags (256 bits to 2 M words)
Self-Powered Backscatter (internal clock, sensor interface support)
˜100 meter range
Moderate cost

Class-4
Active tags
Active transmission (permits tag-speaks-first operating modes)
˜300 to ˜1,000 meter range
Higher cost

In RFID systems where passive receivers (i.e., Class-1 and Class-2 tags) are able to capture enough energy from the transmitted RF to power the tag, no batteries are necessary. In systems where distance prevents powering a tag in this manner, an alternative power source must be used. For these “alternate” systems (e.g., semi-active, semi-passive or battery-assisted), batteries are the most common form of power. This greatly increases read range, and the reliability of tag reads, because the tag does not need power from the reader to respond. Class-3 tags only need a 5 mV signal from the reader in comparison to the 500 mV that Class-1 and Class-2 tags typically need to operate. This 100:1 reduction in power requirement along with the reader's ability to sense a very small backscattered signal permits Class-3 tags to operate out to a free space distance of 100 meters or more compared with a Class-1 range of only about 3 meters. Note that semi-passive and active tags with built in passive mode may also operate in passive mode, using only energy captured from an incoming RF signal to operate and respond, at a shorter distance up to 3 meters.

Active, semi-passive and passive RFID tags may operate within various regions of the radio frequency spectrum. Low-frequency (30 KHz to 500 KHz) tags have low system costs and are limited to short reading ranges. Low frequency tags may be used in security access and animal identification applications for example. Ultra high-frequency (860 MHz to 960 MHz and 2.4 GHz to 2.5 GHz) tags offer increased read ranges and high reading speeds.

A basic RFID communication between an RFID tag and a remote device, e.g., reader, typically begins with the remote device, e.g., reader, sending out signals via radio wave to find a particular RFID tag via singulation or any other method known in the art. The radio wave hits the RFID tag, and the RFID tag recognizes the remote device's signal and may respond thereto. Such response may include exiting a hibernation state, sending a reply, storing data, etc.

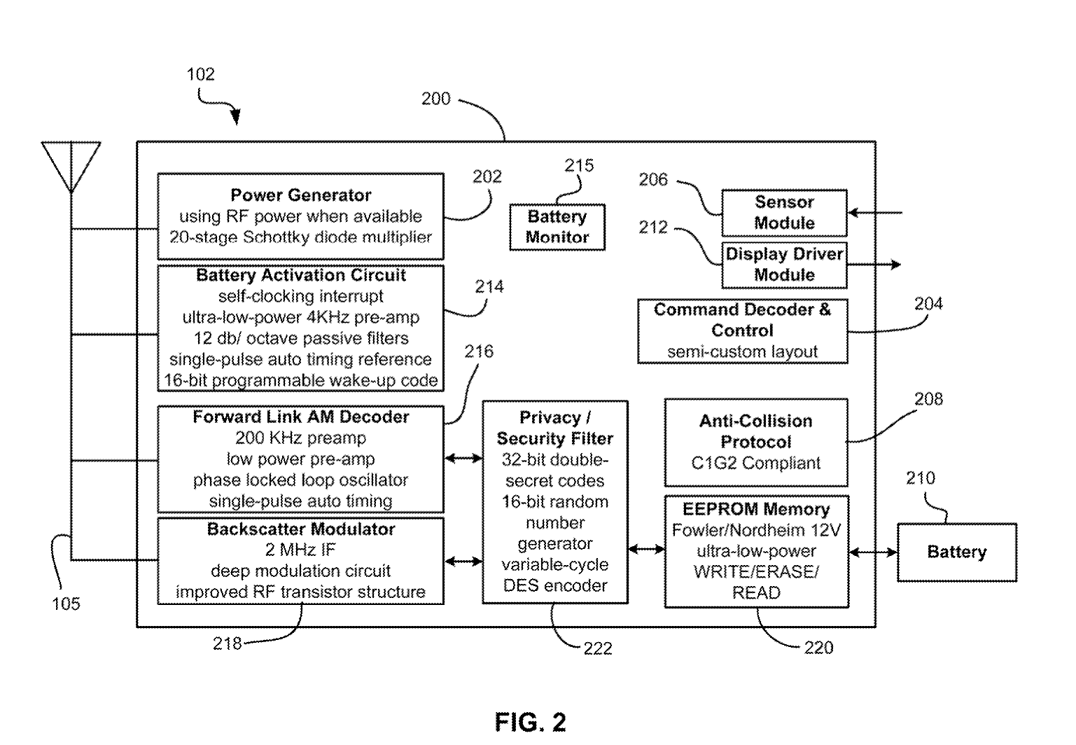

Embodiments of the RFID tag are preferably implemented in conjunction with a Class-3 or higher Class IC chip, which typically contains the processing and control circuitry for most if not all tag operations. FIG. 2 depicts a circuit layout of a Class-3 IC 200 and the various control circuitry according to an illustrative embodiment for implementation in an RFID tag 102. It should be kept in mind that the present invention can be implemented using any type of RFID tag, and the circuit 200 is presented as only one possible implementation.

The Class-3 IC of FIG. 2 can form the core of RFID chips appropriate for many applications such as identification of pallets, cartons, containers, vehicles, or anything where a range of more than 2-3 meters is desired. As shown, the chip 200 includes several circuits including a power generation and regulation circuit 202, a digital command decoder and control circuit 204, a sensor interface module 206, a C1G2 interface protocol circuit 208, and a power source (battery) 210. A display driver module 212 can be added to drive a display.

A forward link AM decoder 216 uses a simplified phase-lock-loop oscillator that requires only a small amount of chip area. Preferably, the circuit 216 requires only a minimum string of reference pulses.

A backscatter modulator block 218 preferably increases the backscatter modulation depth to more than 50%.

A memory cell, e.g., EEPROM, is also present, and preferably has a capacity from several kilobytes to one megabyte or more. In one embodiment, a pure, Fowler-Nordheim direct-tunneling-through-oxide mechanism 220 is present to reduce both the WRITE and ERASE currents to about 2 μA/cell in the EEPROM memory array. Unlike any RFID tags built to date, this permits reliable tag operation at maximum range even when WRITE and ERASE operations are being performed. In other embodiments, the WRITE and ERASE currents may be higher or lower, depending on the type of memory used and its requirements.

Preferably, the amount of memory available on the chip or otherwise is adequate to store data such that the external device need not be in active communication with the remote device, e.g., reader.

The module 200 may also incorporate a security encryption circuit 222 for operating under one or more security schemes, secret handshakes with readers, etc.

The RFID tag may have a dedicated power supply, e.g. battery; may draw power from a power source of the electronic device (e.g., battery, AC adapter, etc.); or both. Further, the RFID tag may include a supplemental power source. Note that while the present description refers to a “supplemental” power source, the supplemental power source may indeed be the sole device that captures energy from outside the tag, be it from solar, RF, kinetic, etc. energy.

Source Synchronization

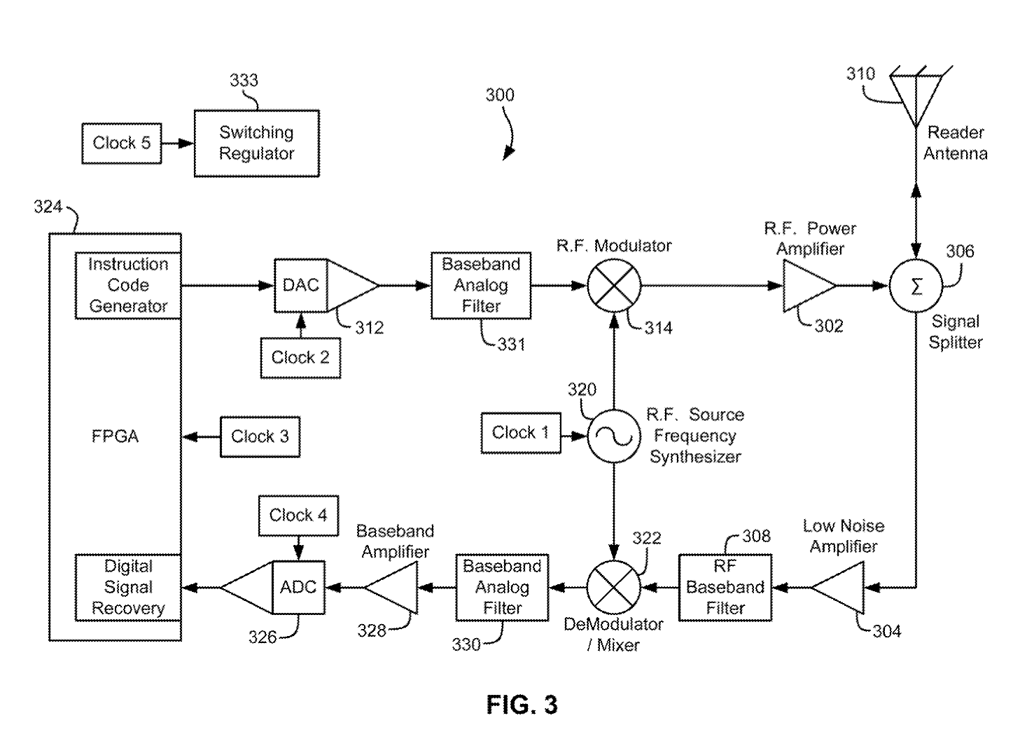

Referring to FIG. 3, in an illustrative RFID reader circuit 300, some of the components in the RFD reader circuit 300 make use of a timing signal, and these components may be affected by noise which is introduced into the signal by timing signals from clocks which are not in synchronization. For example, in FIG. 3, many of the components of the RFID reader circuit 300, including a Radio Frequency (RF) source 320, a switching regulator 333, a Digital-to-Analog (D/A) converter (DAC) 312, and an Analog-to-Digital (A/D) converter (ADC) 326, may use a timing signal to perform their designated functions. The RF source 320 is provided a signal from Clock 1, the A/D converter 326 is provided a timing signal from Clock 4. Each of these clocks are typically crystal oscillator controlled, which means that a crystal oscillator clock provides the timing signal to each component separately. In contrast, the switching regulator 333 is provided a signal from Clock 5, which is typically resistance-capacitance oscillator controlled. Many other components may also use a timing signal in order to perform their designated functions, including, but not limited to: a RF modulator 314, an instruction code generator and a digital signal recovery module which may be part of a processing module 324. The digital processing module 324 may be a field programmable gate array (FPGA), an application specific integrated circuit (ASIC), a processor, an implementation using multiple circuit boards, etc. As shown in FIG. 3, the components are implemented in a FPGA. In additional embodiments, the instruction code generator and the digital signal recovery module may be located in separate components. In addition, some of these components of the RFID reader circuit 300 may be located on separate circuit boards, thereby enhancing the probability that each component may be controlled by a separate timing signal from different clocks.

Because each of these timing devices provide independent timing signals to the individual components of the RFID reader circuit 300, in typical designs, a beat-note between the oscillating signal may develop, which is an undesirable element in the signal, since when the signal is being analyzed by the RFID reader circuit 300, it may confuse some of the components, e.g., it is noise in the signal.

### Illustrative Embodiments

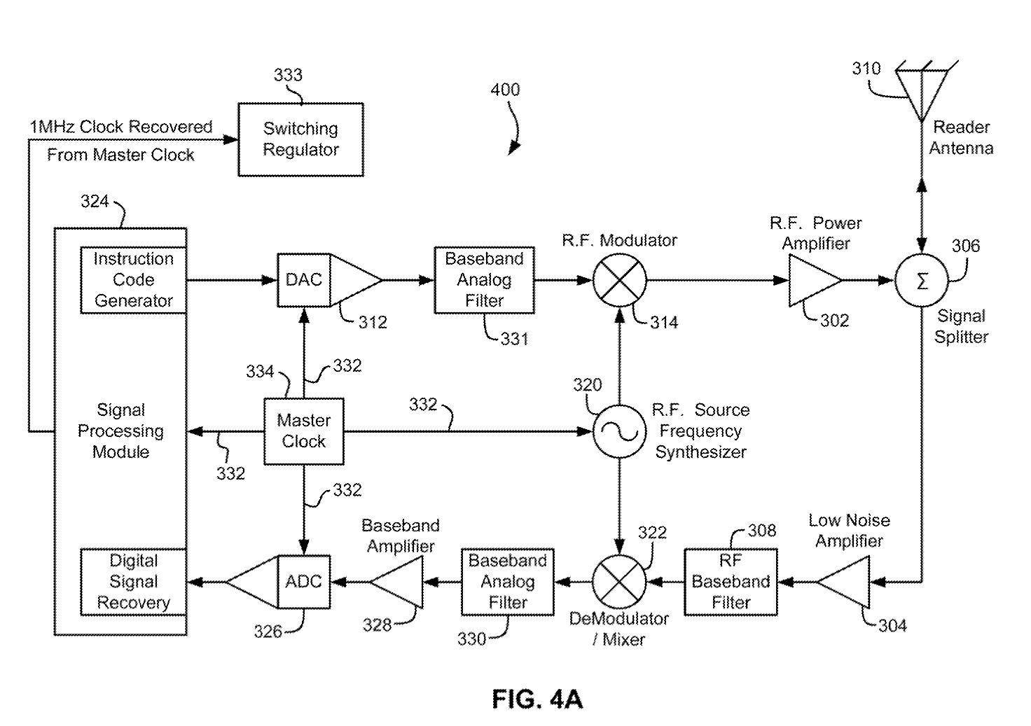

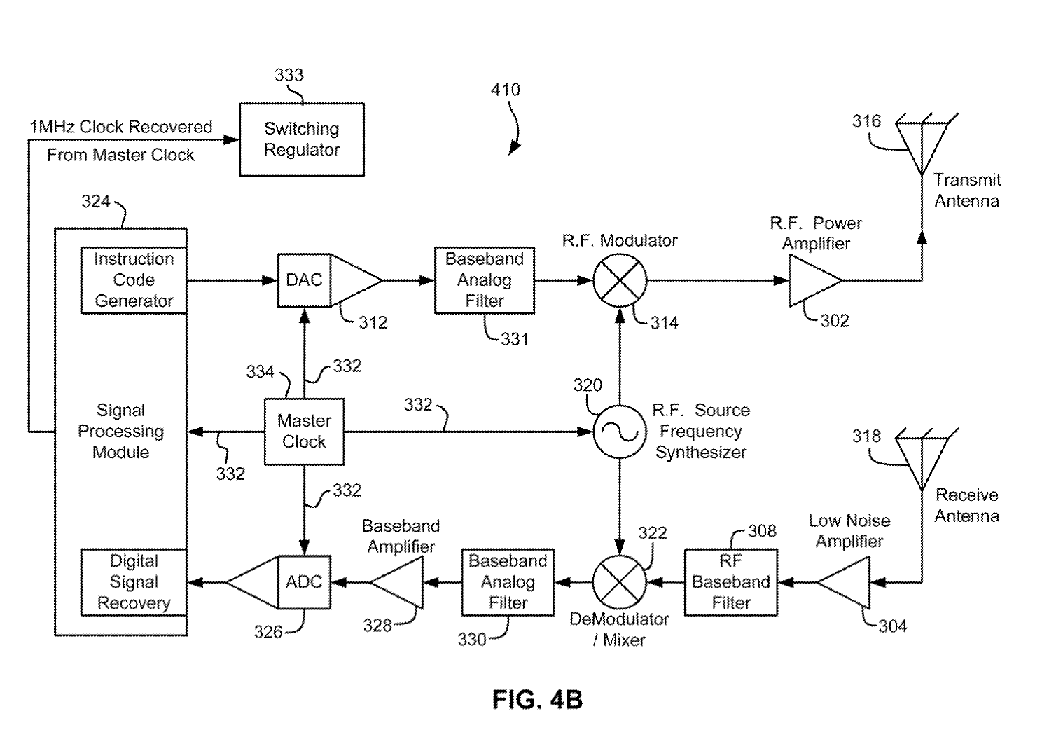

Now referring to FIGS. 4A-4B, to mitigate the problems associated with separate timing signals being provided by separate clocks, a master clock 334 may be used to provide a common timing signal output 332 to all components/circuits of the RFID reader circuit 400, 410, according to various embodiments. A RFID reader circuit 400, 410, according to various embodiments, includes a master clock 334 for providing a timing signal and a timing signal output 332 thereof, a RF source 320 in a transmitting path (from the RF source 320 to the reader antenna 310 or transmit antenna 316, depending on whether the RFID circuit is monostatic 400 or bistatic 410, according to several approaches), the RF source 320 being coupled to the timing signal output 332, a switching regulator 333 synchronized with the timing signal, and an ADC 326 in a receiving path, the ADC 326 being coupled to the timing signal output 332.

In one approach, the timing signal from the master clock 334 may be at 20 MHz, 30 MHz, 40 MHz, 50 MHz, etc. Any timing signal may be used as would be known to one of skill in the art.

In one approach, the RFID reader circuit 400, 410 may include many other components. For example, it may include a demodulator/mixer module 322 in the receiving path, wherein the demodulator/mixer module 322 is adapted to multiply a signal from the RF source 320 with a signal from the RF baseband filter 308 to cancel noise in the signal from the RF baseband filter 308, and a RF modulator 314 coupled to the RF source 320 in the transmitting path, the RF modulator 314 being coupled to the timing signal output 332. The switching regulator 333, in one embodiment, may convert 5 V to 3.3 V. Of course, the switching regulator 333 may convert any received voltage to a voltage that can be used by one or more components/circuits of the RFID circuit 400, 410, according to various embodiments.

According to one embodiment, all components/circuits which comprise a RFID reader may use 3.3V from the switching regulator 333, such as a DAC 312, an ADC 326, the RF modulator 314, the demodulator/mixer 322, a RF power amplifier 302, a low noise amplifier 304, a signal processing module 324, which in one embodiment may be a FPGA, an ASIC, a processor, an implementation using multiple circuit boards, etc. One or both of the instruction code generator for transmitting and the digital signal recovery module for receiving may be implemented in the signal processing module 324, according to various embodiments.

In one embodiment, the signal processing module 324 may generate a 1 MHz clock from the master clock timing signal output 332 (which in one embodiment is 40 MHz) and may feed the 1 MHz clock to the switching regulator 333. By this design, all the components/circuits powered by the switching regulator 333 may have switching noise developed in the switching regulator 333 aligned at 1 MHz. The 1 MHz frequency is chosen such that it is separated (far away) from the incoming RFID tag signal that is decoded by the digital signal recovery module inside the signal processing module 324. In fact, the digital signal recovery module may include a digital comb filter implemented therein to remove noise at every 500 kHz interval. This implementation removes the switching noise prevalent in the system at 1 MHz. Additionally, any and/or all components/circuits of the RFID reader circuit 400, 410, that use a non-tag-response clock may use the timing signal on the timing signal output 332, according to various embodiments. Of course, different frequency clock signals may be used, and the present invention is not limited to generating a 1 MHz clock only, as other frequencies may be implemented as would be known to one of skill in the art.

In some embodiments, a baseband analog filter 331 may be coupled to an input of the RF modulator 314. In more embodiments, a baseband analog filter 330 may be coupled to an output of the demodulator/mixer 322. In additional approaches, a baseband amplifier 328 may be coupled to an output of the baseband analog filter 330.

The various components coupled to the timing signal output 332 may use a clock frequency other than that on the timing signal output 332. Accordingly, logic for altering the timing signal may be present between the components and the timing signal output 332 and/or on the components themselves. Illustrative logic includes clock dividers, clock multipliers, clock shifters, etc. Such logic may be of a type known in the art. As described herein, the “timing signal” is meant to include the raw timing signal and the timing signal output 332, as well as derivatives thereof.

According to one approach, referring to FIG. 4A, the RFID reader circuit 400 may be adapted for monostatic operation. In this approach, the RFID reader circuit 400 may include a signal splitter module 306 coupled to a reader antenna lead, a RF power amplifier 302 in the transmitting path, and a low noise amplifier 304 in the receiving path. An input of the signal splitter module 306 may be coupled to an output of the RF power amplifier 302, an output of the signal splitter module 306 may be coupled to an input of the low noise amplifier 304, and the reader antenna lead may be for coupling to a reader antenna 310 capable of sending and receiving signals.

In an alternative approach, referring to FIG. 4B, the RFID reader circuit 410 may be adapted for bistatic operation. In this approach, the RFID reader circuit 410 may include a transmit antenna lead in the transmitting path for coupling to a transmit antenna 316 capable of sending signals, and a receive antenna lead in the receiving path for coupling to a receive antenna 318 capable of receiving signals.

In one embodiment, components which comprise the transmitting path (e.g., the RF source 320, the RF modulator 314, etc.) may be on the same circuit board as components which comprise the receiving path (e.g., the ADC 326, the digital signal recovery module 324, etc.).

In an alternative embodiment, at least one component which comprises at least a portion of the transmitting path of the RFID reader circuit 400, 410 may be on a separate circuit board than at least one component which comprises at least a portion of the receiving path of the RFID reader circuit 400, 410.

Referring again to FIGS. 1-2,4A-4B, a RFID system includes a plurality of RFID tags 102, and at least one RFID reader 104, the at least one RFID reader 104 including a RFID reader circuit 400, 410. The RFID reader circuit 400, 410 includes a master clock 334 for providing a timing signal and a timing signal output 332 thereof, a RF source 320 in a transmitting path (from the RF source 320 to the reader antenna 310 or transmit antenna 316, depending on whether the RFID circuit is monostatic 400 or bistatic 410, according to several approaches), the RF source 320 being coupled to the timing signal output 332, and an ADC 326 in a receiving path, the ADC 326 being coupled to the timing signal output 332.

Any of the embodiment and/or approaches described above in regard to the RFID reader circuit 400, 410 may be applied to this circuit as well.

In another embodiment, a method for mitigating noise in a RFID reader circuit includes providing a common timing signal (or derivatives thereof) from a master clock to each component and/or circuit in a RFID reader circuit which uses a timing signal, along with providing a common timing signal (or derivatives thereof) from a master clock to a power supply which provides power to the RFID reader circuit.

In one embodiment, the power supply provides power to the RFID circuit through use of a switching regulator, as previously described.

The RFID reader circuit may include any of the embodiments and/or approaches described above, and the method may be applied to RFID reader circuits of types which have not been described above, in various embodiments. is adapted for monostatic operation.

While much of the foregoing has been described in terms of use with RFID systems, it is again stressed that the various embodiments may be used in conjunction with other types of RF devices, such as receive-only RF devices, 1- and 2-way radios, boards and/or circuits for RF devices, etc.

The present description is presented to enable any person skilled in the art to make and use the invention and is provided in the context of particular applications of the invention and their requirements. Various modifications to the disclosed embodiments will be readily apparent to those skilled in the art and the general principles defined herein may be applied to other embodiments and applications without departing from the spirit and scope of the present invention. Thus, the present invention is not intended to be limited to the embodiments shown, but is to be accorded the widest scope consistent with the principles and features disclosed herein.

In particular, various embodiments discussed herein are implemented using the Internet as a means of communicating among a plurality of discrete systems. One skilled in the art will recognize that the present invention is not limited to the use of the Internet as a communication medium and that alternative methods of the invention may accommodate the use of a private intranet, a LAN, a WAN, a PSTN or other means of communication. In addition, various combinations of wired, wireless (e.g., radio frequency) and optical communication links may be utilized.

The program environment in which a present embodiment of the invention may be executed illustratively incorporates one or more general-purpose computers or special-purpose devices such facsimile machines and hand-held computers. Details of such devices (e.g., processor, memory, data storage, input and output devices) are well known and are omitted for the sake of clarity.

It should also be understood that the techniques presented herein might be implemented using a variety of technologies. For example, the methods described herein may be implemented in software running on a computer system, and/or implemented in hardware utilizing either a combination of microprocessors or other specially designed application specific integrated circuits, programmable logic devices, or various combinations thereof. In particular, methods described herein may be implemented by a series of computer-executable instructions residing on a storage medium such as a carrier wave, disk drive, or computer-readable medium. Exemplary forms of carrier waves may be electrical, electromagnetic or optical signals conveying digital data streams along a local network or a publicly accessible network such as the Internet. In addition, although specific embodiments of the invention may employ object-oriented software programming concepts, the invention is not so limited and is easily adapted to employ other forms of directing the operation of a computer.

Various embodiments can also be provided in the form of a computer program product comprising a computer readable medium having computer code thereon. A computer readable medium can include any medium capable of storing computer code thereon for use by a computer, including optical media such as read only and writeable CD and DVD, magnetic memory, semiconductor memory (e.g., FLASH memory and other portable memory cards, etc.), etc. Further, such software can be downloadable or otherwise transferable from one computing device to another via network, wireless link, nonvolatile memory device, etc.

Moreover, any of the devices described herein, including an RFID reader, may be considered a “computer.”

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

What is claimed is:

1. A Radio Frequency Identification (RFID) reader circuit, the reader circuit comprising:
a master clock for providing a timing signal on a timing signal output thereof;
a switching regulator synchronized with the timing signal for providing power to the RFID reader circuit;
a Radio Frequency (RF) source in a transmitting path, the RF source being coupled to the timing signal output; and
an analog-to-digital converter (ADC) in a receiving path, the ADC being coupled to the timing signal output.

2. The RFID reader circuit of claim 1, further comprising a field programmable gate array (FPGA), wherein the FPGA synchronizes the switching regulator with the timing signal.

3. The RFID reader circuit of claim 2, wherein the FPGA uses a digital comb filter to remove noise from the switching regulator prior to digital signal recovery.

4. The RFID reader circuit of claim 3, wherein the noise removed from the switching regulator is a switching frequency derived from the timing signal.

5. The RFID reader circuit of claim 1, further comprising a RF baseband filter coupled between a reader antenna lead and a mixer module in the receiving path, wherein the mixer module is adapted to multiply a signal from the RF source with a signal from the RF baseband filter to cancel noise in the signal from the RF baseband filter.

6. The RFID reader circuit of claim 1, further comprising a RF modulator coupled to the RF source in the transmitting path, the RF modulator being coupled to the timing signal output.

7. The RFID reader circuit of claim 1, further comprising a digital signal recovery module coupled to the timing signal output.

8. The RFID reader circuit of claim 1, wherein the RFID reader circuit is adapted for monostatic operation.

9. The RFID reader circuit of claim 8, further comprising:
a signal splitter module coupled to a reader antenna lead;
a RF power amplifier in the transmitting path; and
a low noise amplifier in the receiving path,
wherein an input of the signal splitter module is coupled to an output of the RF power amplifier,
wherein an output of the signal splitter module is coupled to an input of the low noise amplifier, and
wherein the reader antenna lead is for coupling to a reader antenna capable of sending and receiving signals.

10. The RFID reader circuit of claim 1, wherein the RFID reader circuit is adapted for bistatic operation.

11. The RFID reader circuit of claim 10, further comprising:
a transmit antenna lead in the transmitting path for coupling to a transmit antenna capable of sending signals; and
a receive antenna lead in the receiving path for coupling to a receive antenna capable of receiving signals.

12. The RFID reader circuit of claim 1, wherein components which comprise the transmitting path are on the same circuit board as components which comprise the receiving path.

13. The RFID reader circuit of claim 12, further comprising a digital signal recovery module coupled to the timing signal output.

14. The RFID reader circuit of claim 1, wherein at least one component which comprises at least a portion of a transmitting path of the RFID reader circuit is on a separate circuit board than at least one component which comprises at least a portion of a receiving path of the RFID reader circuit.

15. The RFID reader circuit of claim 14, further comprising a digital signal recovery module coupled to the timing signal output.

16. A Radio Frequency Identification (RFID) system, the system comprising:
a plurality of RFID tags; and
at least one RFID reader, the at least one RFID reader comprising a RFID reader circuit, the circuit comprising:
a master clock for providing a timing signal on a timing signal output thereof;
a Radio Frequency (RF) source in a transmitting path, the RF source being coupled to the timing signal output;
an analog-to-digital converter (ADC) in a receiving path, the ADC being coupled to the timing signal output; and
a digital signal recovery module in the receiving path, the digital signal recovery module being coupled to the timing signal output,
wherein portions of the transmitting path are on a different circuit board than portions of the receiving path.

17. The RFID system of claim 16, wherein the RFID reader circuit further comprises:
a signal splitter module coupled to a reader antenna lead;
a RF power amplifier in the transmitting path; and
a low noise amplifier in the receiving path,
wherein an input of the signal splitter module is coupled to an output of the RF power amplifier,
wherein an output of the signal splitter module is coupled to an input of the low noise amplifier, and
wherein the reader antenna lead is for coupling to a reader antenna capable of sending and receiving signals.

18. The RFID system of claim 16, wherein the RFID reader circuit further comprises:
a transmit antenna lead in the transmitting path for coupling to a transmit antenna capable of sending signals; and
a receive antenna lead in the receiving path for coupling to a receive antenna capable of receiving signals.

19. The RFID system of claim 16, further comprising a field programmable gate array (FPGA), wherein the FPGA synchronizes the switching regulator with the timing signal.

20. The RFID system of claim 19, wherein the FPGA uses a digital comb filter to remove noise from the switching regulator prior to digital signal recovery.

21. The REID system of claim 20, wherein the noise removed from the switching regulator is a switching frequency derived from the timing signal.

22. A method for mitigating noise in a Radio Frequency Identification (RFID) reader circuit, the method comprising providing a common timing signal or derivatives thereof from a master clock to each component in a RFID reader circuit and to a power supply.

23. The method of claim 22, wherein the RFID reader circuit is adapted for monostatic operation.

24. The method of claim 22, wherein the RFID reader circuit is adapted for bistatic operation.

25. The method of claim 22, wherein components which comprise a transmitting path of the RFID reader circuit are on the same circuit board as components which comprise a receiving path of the RFID reader circuit.

26. The method of claim 22, wherein at least one component which comprises at least a portion of a transmitting path of the RFID reader circuit is on a separate circuit board than at least one component which comprises at least a portion of a receiving path of the RFID reader circuit.
